(19) United States
(12) Patent Application Publication
(10) Pub. No.: US 2025/0048038 A1
(43) Pub. Date: Feb. 6, 2025

(54) VIBRATION DETECTOR, WEARABLE DEVICE, AND PIPING INSPECTION APPARATUS

(71) Applicant: Masayuki FUJISHIMA, Kanagawa (JP)

(72) Inventor: Masayuki FUJISHIMA, Kanagawa (JP)

(21) Appl. No.: 18/780,622

(22) Filed: Jul. 23, 2024

(30) Foreign Application Priority Data
Jul. 31, 2023 (JP) 2023-124446
Feb. 28, 2024 (JP) 2024-028575

(51) Int. Cl. H04R 17/02; B81B 3/00; G01M 3/24

(52) U.S. Cl. CPC H04R 17/02; B81B 3/0027; G01M 3/243; B81B 2203/0118; B81B 2203/0127

(57) ABSTRACT

A vibration detector includes a diaphragm including a fixed end forming a line segment extending in a first direction; and a reference point farthest from the fixed end in a second direction orthogonal to the first direction; and a support portion supporting the diaphragm at the fixed end. The vibration detector satisfies a formula below:

$$\frac{{L}^{3}}{8 {W}_{0}} < {\int }_{0}^{L} \int \frac{1}{W ( x )} {\int }_{0}^{x} W ( ξ ) ξ d ξ {dx}^{2}$$

where
x denotes a distance in the second direction between the reference point and a point on the diaphragm,
ξ denotes a point within a distance of x from the reference point in the second direction,
W(x) denotes a width of the diaphragm at the distance of x in the first direction,
L denotes a length of the diaphragm between the fixed end and the reference point in the second direction, and
W0 denotes a width of the diaphragm in the first direction when the diaphragm has a rectangular shape.

### CROSS-REFERENCE TO RELATED APPLICATIONS

This patent application is based on and claims priority pursuant to 35 U.S.C. § 119(a) to Japanese Patent Application No. 2023-124446, filed on Jul. 31, 2023 and Japanese Patent Application No. 2024-028575, filed on Feb. 28, 2024, in the Japan Patent Office, the entire disclosure of which is hereby incorporated by reference herein.

### BACKGROUND

### Technical Field

Embodiment of the present disclosure relate to a vibration detector, a wearable device, and a piping inspection apparatus.

### Related Art

A micro-electromechanical systems (MEMS) transducer includes a substrate and multiple tapered transducer beams. Each tapered transducer beam includes a piezoelectric layer that converts applied pressure into voltage, and a pair of electrode layers sandwiching the piezoelectric layer. Each tapered transducer beam has a beam base end, a beam tip, and a beam body portion located between the beam base end and the beam tip. The beam body portion tapers from the beam base end toward the beam tip. The tapered transducer beams are connected to the substrate in a cantilevered arrangement by attaching the beam base end to the substrate. The tips of the multiple tapered transducer beams converge toward a common point, with each beam body and beam tip not being bonded to the substrate. The beam tips include pointed ends, and these pointed ends converge to approximately a single point. This configuration is characteristic of the disclosed MEMS transducer.

### SUMMARY

An embodiment of the present disclosure provides a vibration detector comprising: a diaphragm including: a fixed end forming a line segment extending in a first direction; and a reference point farthest from the fixed end on an outer periphery of the diaphragm in a second direction orthogonal to the first direction; and a support portion supporting the diaphragm at the fixed end to allow the diaphragm to vibrate. The vibration detector satisfies a formula below:

$$\frac{{L}^{3}}{8 {W}_{0}} < {\int }_{0}^{L} \int \frac{1}{W ( x )} {\int }_{0}^{x} W ( ξ ) ξ d ξ {dx}^{2}$$

where
x denotes a distance in the second direction between the reference point and a point on the diaphragm,
ξ denotes a point within a distance of x from the reference point in the second direction,
W(x) denotes a width of the diaphragm at the distance of x in the first direction,
L denotes a length of the diaphragm between the fixed end and the reference point in the second direction, and
W0 denotes a width of the diaphragm in the first direction when the diaphragm has a rectangular shape with a length of L and a constant area.

An embodiment of the present disclosure provides a vibration detector including: a diaphragm including a fixed end forming a line segment extending in a first direction; and a support portion supporting the diaphragm at the fixed end to allow the diaphragm to vibrate. A width of the diaphragm in the first direction is maximum at a position farther from the fixed end than a midpoint of a line segment shortest among line segments between the fixed end and an outer periphery of the diaphragm in a second direction orthogonal to the first direction.

An embodiment of the present disclosure provides a vibration detector includes: a cantilever beam including: a support portion; and a diaphragm. The diaphragm includes: a fixed end fixed to the support portion; and a tip end farther from the fixed end in a first direction, the tip end vibratile in a second direction intersecting the first direction. The diaphragm has a part having a width in a third direction intersecting the first direction and the second direction, and the width of the part continuously increases from the fixed end toward the tip end in the first direction.

### BRIEF DESCRIPTION OF THE DRAWINGS

A more complete appreciation of embodiments of the present disclosure and many of the attendant advantages and features thereof can be readily obtained and understood from the following detailed description with reference to the accompanying drawings, wherein:

FIG. 1 is a schematic diagram of a vibration detector according to a first embodiment of the present disclosure;

FIG. 2 is a cross-sectional view of the vibration detector in FIG. 1;

FIG. 3 is a plan view of a fixed end;

FIG. 4A is a plan view of a fixed end according to a modification of an embodiment of the present disclosure;

FIG. 4B is a plan view of a fixed end according to a modification of an embodiment of the present disclosure;

FIG. 5 is a cross-sectional view of a fixed end;

FIG. 6 is a diagram illustrating the amount of deflection of a cantilever beam;

FIG. 7 is a diagram illustrating a shape of a cantilever beam model according to a first embodiment of the present disclosure;

FIG. 8 is a diagram illustrating a shape of a cantilever beam according to a first comparative example;

FIG. 9 is a diagram illustrating a shape of a cantilever beam model according to a first embodiment of the present disclosure;

FIGS. 10A, 10B, 10C, 10D, 10E, and 10F are diagrams each illustrating a model used for simulation;

FIG. 11 is a graph representing simulation results for comparing the amount of deflection;

FIGS. 12A, 12B, 12C, and 12D are diagrams each illustrating a model used for a resonance frequency simulation;

FIG. 13 is a graph of simulation results of resonant frequency;

FIG. 14 is a diagram for comparing the center of gravity for the first comparative example of FIG. 8 with that of the model of the first embodiment of FIG. 7;

FIG. 15 is a diagram of a model used for the simulation of resonant frequency;

FIG. 16 is a graph of simulation results of resonant frequency;

FIG. 17A is a plan view of a vibration detector according to a first modification of an embodiment of the present disclosure;

FIG. 17B is a cross-sectional view of the vibration detector of FIG. 17A;

FIG. 18A is a plan view of a vibration detector according to a second modification of an embodiment of the present disclosure;

FIG. 18B is a cross-sectional view of the vibration detector of FIG. 18A;

FIG. 19A is a plan view of a vibration detector according to a third modification of an embodiment of the present disclosure;

FIG. 19B is a cross-sectional view of the vibration detector of FIG. 19A;

FIG. 20A is a plan view of a vibration detector according to a fourth modification of an embodiment of the present disclosure;

FIG. 20B is a cross-sectional view of the vibration detector of FIG. 20A;

FIG. 21A is a plan view of a vibration detector according to a fifth modification of an embodiment of the present disclosure;

FIG. 21B is a cross-sectional view of the vibration detector of FIG. 21A;

FIGS. 22A, 22B, 22C, and 22D are diagrams each illustrating a different relative position between a distortion detector and a support portion;

FIG. 23A is a diagram of a vibration detector worn on an ear according to a second embodiment;

FIG. 23B is a diagram of a vibration detector worn on the wrist according to the second embodiment; and

FIG. 24 is a diagram of a third embodiment.

The accompanying drawings are intended to depict embodiments of the present disclosure and should not be interpreted to limit the scope thereof. The accompanying drawings are not to be considered as drawn to scale unless explicitly noted. Also, identical or similar reference numerals designate identical or similar components throughout the several views.

### DETAILED DESCRIPTION

In describing embodiments illustrated in the drawings, specific terminology is employed for the sake of clarity. However, the disclosure of this specification is not intended to be limited to the specific terminology so selected and it is to be understood that each specific element includes all technical equivalents that have a similar function, operate in a similar manner, and achieve a similar result.

Referring now to the drawings, embodiments of the present disclosure are described below. As used herein, the singular forms “a,” “an,” and “the” are intended to include the plural forms as well, unless the context clearly indicates otherwise.

According to one aspect of the present disclosure, a vibration detector with enhanced sensitivity is provided.

A microphone is an example of a vibration detector that detects heart rate with a wearable sensor. A microphone receives sound waves at a vibrator and converts the displacement of a diaphragm caused by the sound waves into electrical signals. A microphone for measuring sounds in the audible range is used in acoustic devices, household electric appliances, and smartphones. From the viewpoint of the detection principle, MEMS microphones are classified into capacitance types and piezoelectric types.

A capacitive microphone detects the displacement of the movable electrode by detecting the electromotive force generated by changes in capacitance between the parallel plate electrodes of the movable electrode and the fixed electrode that receive the sound waves, converting the sound wave into electrical signals. The capacitive microphone has high sensitivity and low noise floor due to the changes in capacitance between the parallel plate electrodes of the movable and fixed electrodes that receive sound waves. This results in a high signal-to-noise ratio (S/N ratio) and excellent frequency characteristics, making it the most widely used type of microphone today. Reducing the distance between electrodes is advantageous for increasing the sensitivity of the device. As such, recent advancements have reduced the electrode distance to approximately 1 km. However, with a small electrode distance and a large displacement of the diaphragm, the diaphragm comes into contact with the opposed electrode, resulting in failure to reduce the resonance frequency, i.e., to enhance the sensitivity of the low-frequency range. In addition, an input power source is required to apply a constant electric field to between the parallel plate for charging during detection. The application of this electric field generates an attractive force between the parallel plate electrode, resulting in a narrow dynamic range. Further, it has been pointed out that the air resistance applied to the movable electrode significantly affects its characteristics.

A piezoelectric microphone detects sound waves by converting the displacement caused by the sound waves into electrical signals using piezoelectric effects. This allows for a simple detection configuration, an uncomplicated device manufacturing process, and suitably for miniaturization. Further, the absence of an input power supply allows for a simpler passive circuit. Further, the piezoelectric microphone has a wider dynamic range than the capacitive microphone. However, it has been pointed out that the piezoelectric MEMS microphone has relatively lower characteristics in terms of sensitivity, noise characteristics, and S/N ratio than the capacitance MEMS microphone. Thus, in order to increase the S/N ratio, the sensitivity needs to be enhanced and the noise characteristics need to be increased. A piezoelectric microphone using a cantilever beam structure has also been proposed to reduce noise caused by the residual stress of the piezoelectric film. In recent years, it has become well-known that new applications for such MEMS microphones are being proposed. These include their incorporation into wearable devices to acquire vital data such as hear rate and respiration, and their use in infrastructure monitoring sensors to detect anomalies in pipelines. Consequently, the demand for the MEMS microphones is increasing.

In new applications of MEMS microphones, such as a wearable device that acquires vital data including a heart rate and respiration, high sensitivity is required in low-frequency bands around 100 Hz.

However, in capacitive microphone, if the electrode distance is reduced and the displacement of the diaphragm is increased to achieve higher sensitivity in the low-frequency range, the diaphragm comes into contact with the opposed electrode. This results in failure to reduce the resonant frequency, i.e., to enhance the sensitivity of the low-frequency range.

Although technologies for reducing noise in low-frequency bands for piezoelectric microphones have been proposed, there are few research examples focused on enhancing sensitivity itself.

### First Embodiment

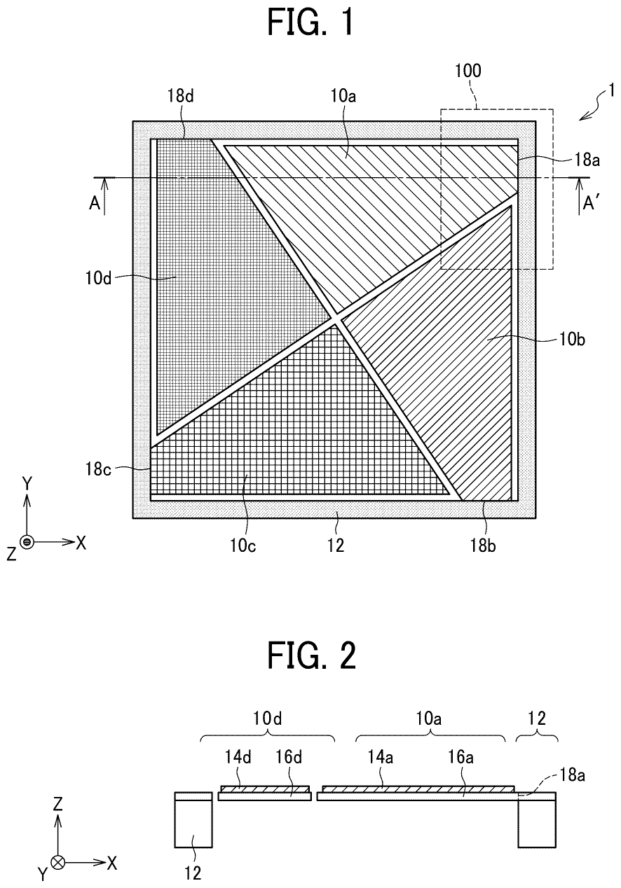

A first embodiment of the present disclosure is illustrated in FIG. 1. A vibration detector 1 includes diaphragms 10a, 10b, 10c, and 10d and a support portion 12 having a rectangular shape surrounding the periphery of the entire diaphragms 10a, 10b, 10c, and 10d.

In the following description, the four diaphragms 10a, 10b, 10c, and 10d are sometimes referred to collectively as diaphragm 10a or 10. Similarly, four fixed ends 18a, 18b, 18c, and 18d are referred to collectively as fixed ends 18a or 18.

Each diaphragm 10 is a quadrilateral diaphragm having at least one acute angle. The four diaphragms 10a, 10b, 10c, and 10d are arranged point-symmetrically within the frame of the support portion 12, and have a shape that forms a substantially square when combined. The support portion 12 supports the diaphragms 10a, 10b, 10c, and 10d by fixing one side of each diaphragm as a fixed end (18a, 18b, 18c, and 18d). In this case, the fixed ends 18a, 18b, 18c, and 18d are defined as the line segments connecting the two endpoints of the portions where the diaphragms 10a, 10b, 10c, and 10d are supported by the support portion 12. In the periphery of the diaphragm 10, the sides, which are free ends, other than the fixed ends 18a, 18b, 18c, and 18d are not in contact with adjacent diaphragms 10a, 10b, 10c, and 10d and the support portion 12. In other words, the diaphragms 10a, 10b, 10c, and 10d serve to vibrate around the fixed ends 18a, 18b, 18c, and 18d in response to external vibration such as sound. The fixed ends 18a, 18b, 18c, and 18d described in the present embodiment each are not limited to one side in the XY plan view. The fixed ends 18a, 18b, 18c, and 18d may be formed, for example, by multiple adjacent straight lines in the XY plane view, and may also include some curved portions.

The fixed ends 18a, 18b, 18c, and 18d of the present embodiment refers to a line segment connecting both ends of the portions where the diaphragms 10a, 10b, 10c, and 10d are supported by the support portion 12. The four diaphragms 10a, 10b, 10c, and 10d have fixed ends 18a, 18b, 18c, and 18d, respectively.

The support portion 12 surrounds the four diaphragms 10a, 10b, 10c, and 10d and has a frame shape with a constant width. The four diaphragms 10a, 10b, 10c, and 10d are combined to form a substantially square shape, and their outer periphery also forms a substantially square shape. Since the vibration detector 1 is substantially square, multiple vibration detectors 1 can be regularly arranged. The outer shape of the support portion 12 allows multiple support portions to be aligned in a straight line both vertically and horizontally. During the semiconductor manufacturing process, the vibration detectors 1 can be cut and separated along a straight dicing line. Thus, the manufacturing cost can be reduced.

FIG. 2 is an A-A′ cross-sectional view of the vibration detector in FIG. 1. In FIG. 2, the cross section of two diaphragms 10a and 10d are illustrated. The diaphragms 10a and 10d include distortion detectors 14a and 14d and diaphragm substrates 16a and 16d, respectively, which are laminated. The boundary between the support portion 12 and the diaphragm 10a is the fixed end 18a. In the A-A′ cross section, the diaphragm 10d is not connected to the support portion 12. The support portion 12 is not in contact with the diaphragm 10d, with a certain space at the boundary between them. In the following description, four distortion detectors 14a, 14b, 14c, and 14d are sometimes referred to collectively as distortion detector 14a or 14. Similarly, the four diaphragm substrates 16a, 16b, 16c, and 16d are also referred to collectively as diaphragm substrate 16a or 16.

The distortion detector 14a includes a piezoelectric film formed of a piezoelectric material. As a material of the piezoelectric film, a material that can be formed into a thin film, such as lead zirconate titanate (PZT), potassium sodium niobate (KNN), or aluminum nitride (AlN), is selected. The piezoelectric film is sandwiched between a lower electrode and an upper electrode. When an external force causes the piezoelectric film to distort, a potential difference occurs between the upper electrode and the lower electrode. Detecting this potential difference allows for the detection of the distortion caused by the vibration.

The diaphragm substrate 16a is made of silicon, i.e., a silicon-based substrate. The silicon substrate has high crystallinity and vibrates flexibly without breaking. The thickness of the diaphragm substrate 16a, which allows the diaphragm 10a to vibrate properly, ranges from a few microns to several tens of microns. The diaphragm substrate 16a is fabricated through the MEMS semiconductor process.

The support portion 12 and the diaphragm substrate 16 are made of, for example, silicon. The support portion 12 may be formed of multiple layers, including an active silicon layer and a silicon oxide layer. The diaphragm substrate 16 may be formed from the same silicon layer as any layer of the layered structure of the support portion 12. The thickness of the support portion 12 is preferably about 200 to 600 microns, which is easy to handle as a wafer in the semiconductor process. The support portion 12 has mechanical strength as the outer shape of the vibration detector 1 and has strength suitable for a bonding process of the semiconductor process. The back surface of the support part 12 is fixed to a semiconductor package with adhesive. As the electrical connection, an electrode pad on the vibration detector 1 is connected to an electrode pad on the semiconductor package by wire bonding. This allows an electrical signal to be extracted from the semiconductor package.

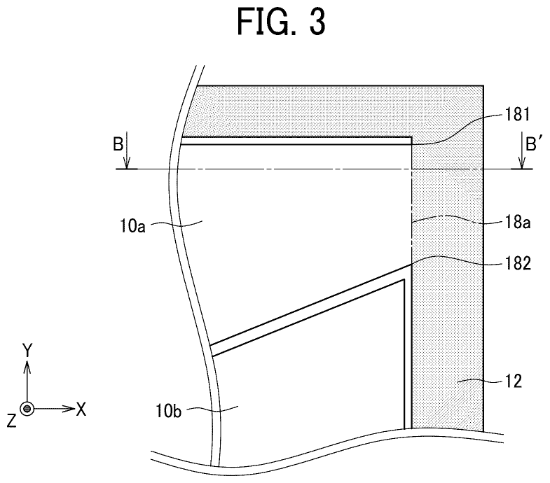

FIG. 3 illustrates an area 100 in FIG. 1. FIG. 3 is an enlarged view of the fixed end 18a of one diaphragm 10a among the four diaphragms 10a, 10b, 10c, and 10d. The following describes the fixed end 18a.

The fixed end 18a is a line segment connecting both endpoints of the boundary between the support portion 12 and the diaphragm 10a. The fixed end 18a is aligned with a line segment connecting both endpoints 181 and 182 of the portion where the diaphragm 10a is supported by the support portion 12. The fixed end 18a is joined to the support portion 12.

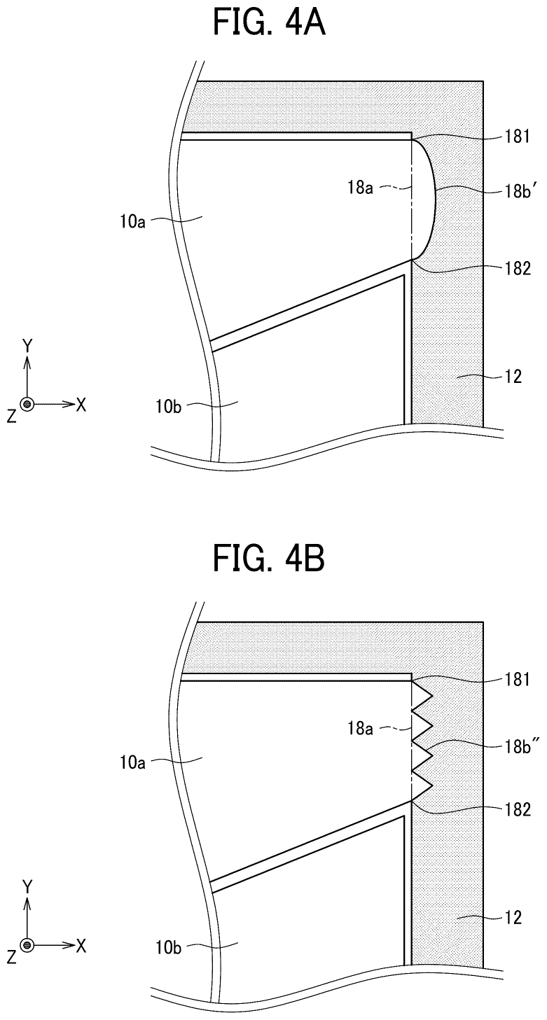

FIGS. 4A and 4B are diagrams each illustrating another example of a fixed end. In FIG. 4A, in the XY plan view, the boundary between the support portion 12 and the diaphragm 10a supported by the support portion 12 forms a curved line 18b′. In this case, the support portion 12 is shaped to be concave along the curved line 18b′, supporting the diaphragm 10a at their boundary formed by the curved line 18b′. The fixed end 18a is defined by a line segment, which is a dashed line in FIG. 4A, connecting the endpoints 181 and 182 of the curved line 18b′. In FIG. 4B, in the XY plan view, the boundary between the support portion 12 and the diaphragm 10a supported by the support portion 12 forms a zigzag line 18b″ formed of multiple straight lines in different directions. In FIG. 4B, the support portion 12 is shaped to be concave along the zigzag line 18b″, supporting the diaphragm 10a at their boundary formed by the zigzag line 18b″. The fixed end 18a is defined by a line segment, which is a dashed line in FIG. 4B, connecting the endpoints 181 and 182 of the boundary formed by the zigzag line 18b″. The boundary between the support portion 12 and the diaphragm 10a is not limited to those of FIGS. 3, 4A, and 4B, and can be appropriately changed. The two endpoints 181 and 182 of the boundary refer to the start and end points of a continuous line where the support portion 12 supports the diaphragm 10a.

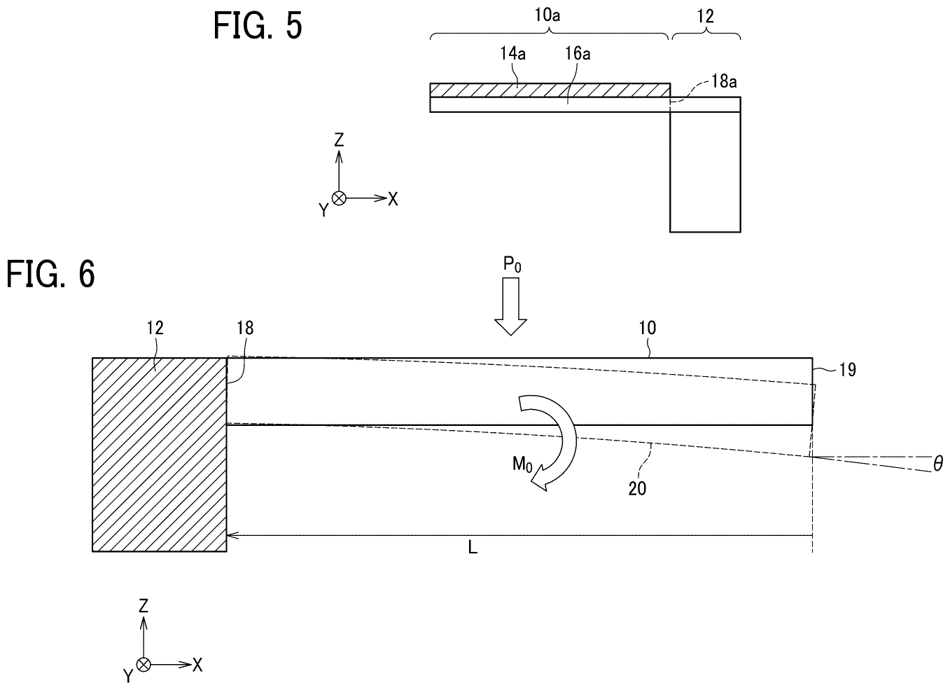

FIG. 5 is a B-B′ cross-sectional view of the vibration detector in FIG. 1 The diaphragm 10a includes a diaphragm substrate 16a and a distortion detector 14a. The support portion 12 and the diaphragm substrate 16 are made of, for example, silicon. The support portion 12 may be formed of multiple layers, including an active silicon layer and a silicon oxide layer. The diaphragm substrate 16 may be formed from the same silicon layer as any layer of the layered structure of the support portion 12. In the present embodiment, the diaphragm substrate 16a flexibly bends and vibrates at the boundary between the support portion 12 and the diaphragm substrate 16a. The boundary between the support portion 12 and the diaphragm 10a can be distinguished by the presence or absence of a layer below (e.g., upstream from) the diaphragm substrate 16a in the Z-direction. The support portion 12 is formed of multiple layers, including an active silicon layer and a silicon oxide layer, which are placed below, i.e., upstream from the diaphragm substrate 16a in the Z-direction. The support portion 12 serves to secure the entire device. In the plane viewed in the Y-direction in FIG. 5, the line segment indicated by a broken line represents the boundary, forming the fixed end 18a. In FIGS. 4A and 4B, the boundary (e.g., the curved line and the zigzag line) differs from the fixed end 18a.

The fixed end 18a is defined by the line segment as illustrated in FIG. 3 and the line segment as illustrated in FIG. 5.

The following describes the sensitivity of the diaphragm 10. The sensitivity represents the extent to which external vibrations can be detected. Higher sensitivity allows the detection of weak external vibrations, such as smaller sounds. The vibration detector 1 of the present embodiment is expected to have a sensitivity that is about 1.5 times higher than that of a comparative example described later.

FIG. 6 is a diagram illustrating a model of the diaphragm 10a, illustrating the amount of deflection of a cantilever beam. The broken line illustrated in FIG. 6 represents a diaphragm 20 deformed by moment M0 generated by acoustic pressure P0. The angle indicated by the broken line is defined as a deflection angle θ. The amount of deflection is indicated by an angle as the deflection angle θ.

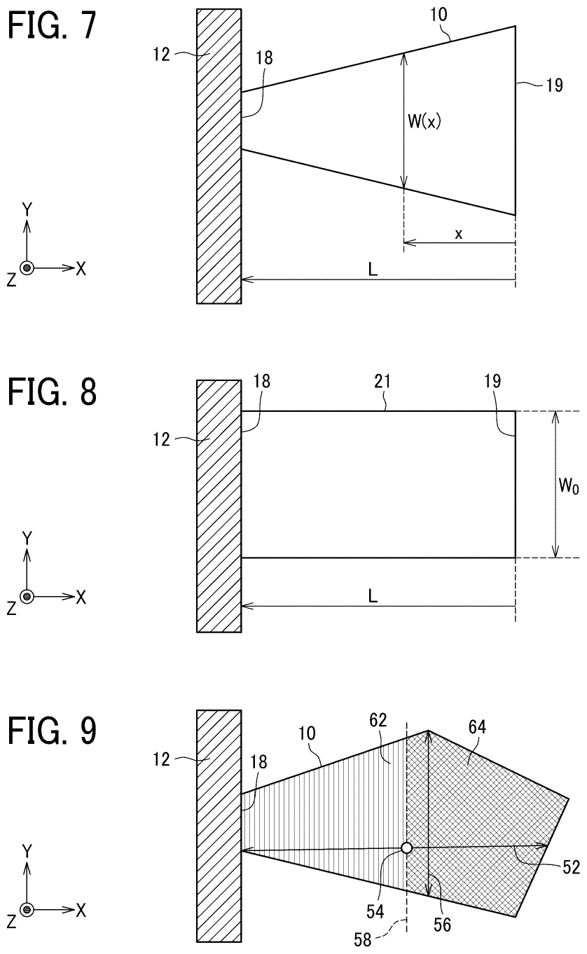

FIG. 7 is a diagram illustrating a shape of a cantilever beam model according to the present embodiment. FIG. 7 illustrates one example shape of the diaphragm 10.

The charges generated in the distortion detector 14 in response to incident external vibrations, such as sounds, are proportional to the amount of distortion in the distortion detector 14. The amount of distortion dz/dx, which corresponds to the deflection angle θ (i.e., the amount of distortion dx/dx=the deflection angle θ), of the distortion detector 14 is given by following formula, using a distance x in the −X-direction from the tip end 19 of the beam to the fixed end 18. The tip end 19 refers to a point on the outer periphery of the diaphragm 10, which is farthest from the fixed end 18 in a direction (i.e., the X-direction) orthogonal to the line segment of the fixed end 18.

$$\frac{dz}{dx} = \int \frac{{d}^{2} z}{{dx}^{2}} dx = \int \frac{M ( x )}{EI ( x )} dx = \frac{12}{{Et}^{3}} \int \frac{M ( x )}{W ( x )} dx \qquad [ Formula 2 ]$$

The signs dz and dx represent minute changes along the X-axis and the Z-axis, respectively, as illustrated in FIG. 7.

M(x) indicates a bending moment at position x, W(x) indicates a width of the diaphragm at the position x along the line segment of the fixed end, E indicates Young's modulus, I(x) indicates a moment of inertia at the position x, and t is a thickness of the diaphragm 10 (i.e., its width in the Z-axis direction). It is assumed that the thickness t of the diaphragm 10 is constant.

The following describes a method of calculating the bending moment M(x) at the position x when the acoustic pressure P0 is applied to the diaphragm 10. The magnitude of the load acting on the infinitesimal length dξ is W(ξ)P0dξ. Thus, a bending moment at position ξ is expressed by W(ξ)ξP0dξ. However, ξ represents any position within the interval from tip end 19 to a point at distance x. The bending moment M(x) at a distance x is obtained by integrating W(ξ)ξP0dξ from the tip end 19 (x=0) to the point at distance x, and can be written as follows. It is assumed that the direction in which the acoustic pressure P0 is applied is parallel to the Z-axis, and that the acoustic pressure is constant in all areas of the model.

$$M ( x ) = {\int }_{0}^{x} W ( ξ ) ξ {P}_{0} d ξ \qquad [ Formula 3 ]$$

The sum of the amount of distortion dz/dx detected by the distortion detector 14 from the tip end 19 (x=0) of the cantilever beam to the fixed end 18 (X=L) is given by the following formula.

$${\int }_{0}^{\tilde{L}} \frac{dz}{dx} dx = \frac{12}{{Et}^{3}} {\int }_{0}^{L} \frac{1}{W ( x )} {\int }_{0}^{x} W ( ξ ) ξ {P}_{0} d ξ {dx}^{2} \qquad [ Formula 4 ]$$

In the formula, L indicates a length from the fixed end 18 to the tip end 19 as a reference point of the diaphragm 10, which is farthest in the direction (X-axis direction) orthogonal to the line segment of the fixed end 18.

FIG. 8 is a diagram of a cantilever beam according to a first comparative example. The beam, or a diaphragm 21, according to the first comparative example is rectangular. The diaphragm 21 has a constant width W0. The length L of the beam according to the present comparative example is equal to that of the model of the present embodiment described in FIG. 7. It is assumed that the area of the model of the first comparative example is equal to that of the model of the present embodiment. In the comparative example, the sum of the amount of distortion dz/dx detected by the distortion detector 14 from the tip end 19 (x=0) of the cantilever beam to the fixed end 18 (X=L) is given by the following formula.

$${\int }_{0}^{L} \frac{dz}{dx} dx = {\int }_{0}^{L} \frac{2 {P}_{0}}{{EW}_{0} {t}^{3}} ( {x}^{3} - {L}^{3} ) dx = \frac{3 {P}_{0} {L}^{3}}{2 {EW}_{0} {t}^{3}} \qquad [ Formula 5 ]$$

Compared to the first comparative example, a larger deformation dz/dx results in a greater deflection angle θ for the same pressure (i.e., the acoustic pressure P0). This enhances the sensitivity of the vibration detector 1. In other words, the following formula is valid, leading to an enhanced sensitivity.

$$\frac{3 {P}_{0} {L}^{3}}{2 {EW}_{0} {t}^{3}} < \frac{12}{{Et}^{3}} {\int }_{0}^{L} \int \frac{1}{W ( x )} {\int }_{0}^{x} W ( ξ ) ξ {P}_{0} d ξ {dx}^{2} \qquad [ Formula 6 ]$$

When the Young's modulus E, the thickness t, and the acoustic pressure P0 of both sides are eliminated from the above formula, the following formula 7 is derived.

$$\frac{{L}^{3}}{8 {W}_{0}} < {\int }_{0}^{L} \int \frac{1}{W ( x )} {\int }_{0}^{x} W ( ξ ) ξ d ξ {dx}^{2} \qquad [ Formula 7 ]$$

The sensitivity can be enhanced by designing the shape of the diaphragm 10 to widen from the fixed end 18 to the tip end 19 in the X-direction, satisfying this condition. Additionally, one method to evaluate the shape of the actually fabricated diaphragm 10 is to use microscopic photographs. By detecting the images, the area, which is the integral value of the position information, can be quantified through image processing. For example, using a digital microscope (VHX-8000) manufactured by Keyence Corporation allows for the quantitative calculation of areas of any shapes and moments derived from distances. Additionally, assuming mass and density enables the calculation of the center of gravity and other related values.

FIG. 9 is a diagram illustrating a shape of a cantilever beam model according to the first embodiment of the present disclosure. FIG. 9 illustrates features that further enhance the effects of the present embodiment. In the present embodiment, when the area of the diaphragm 10 is divided into two by a straight line 58 passing through a midpoint 54 on a line segment 52 in a direction (i.e., the Y-direction) parallel to the line segment of the fixed end 18, a first area 62 closer to the fixed end 18 and a second area 64 closer to the tip end, which is the other area of the diaphragm 10 opposite to the fixed end 18 are obtained. The line segment 52 is the shortest among line segments in the direction (i.e., the X-direction) orthogonal to the line segment of the fixed end 18, connecting the fixed end 18 and points on the outer periphery of the diaphragm 10. In this case, the second area 64 is larger than the first area 62.

The following describes the features of the shape that further enhances the effects of the present embodiment from another perspective. FIG. 9 highlights the width of the diaphragm 10.

In the present embodiment, when taking a midpoint 54 of a line segment 52, the width of the diaphragm 10 in the direction (i.e., the Y-direction) parallel to the line segment of the fixed end 18 is the largest at a position farther from the fixed end 18 than the midpoint 54 in the direction (i.e., the X-direction) orthogonal to the line segment of the fixed end 18. As described above, the line segment 52 is the shortest among line segments in the direction (i.e., the X-direction) orthogonal to the line segment of the fixed end 18, connecting the fixed end 18 and points on the outer periphery of the diaphragm 10. In other words, the maximum width 56 of the diaphragm 10 in the direction (i.e., the Y-direction) parallel to the line segment of the fixed end 18 is located at a position farther from the fixed end 18 than the midpoint 54. This enhances the sensitivity of the vibration detector 1.

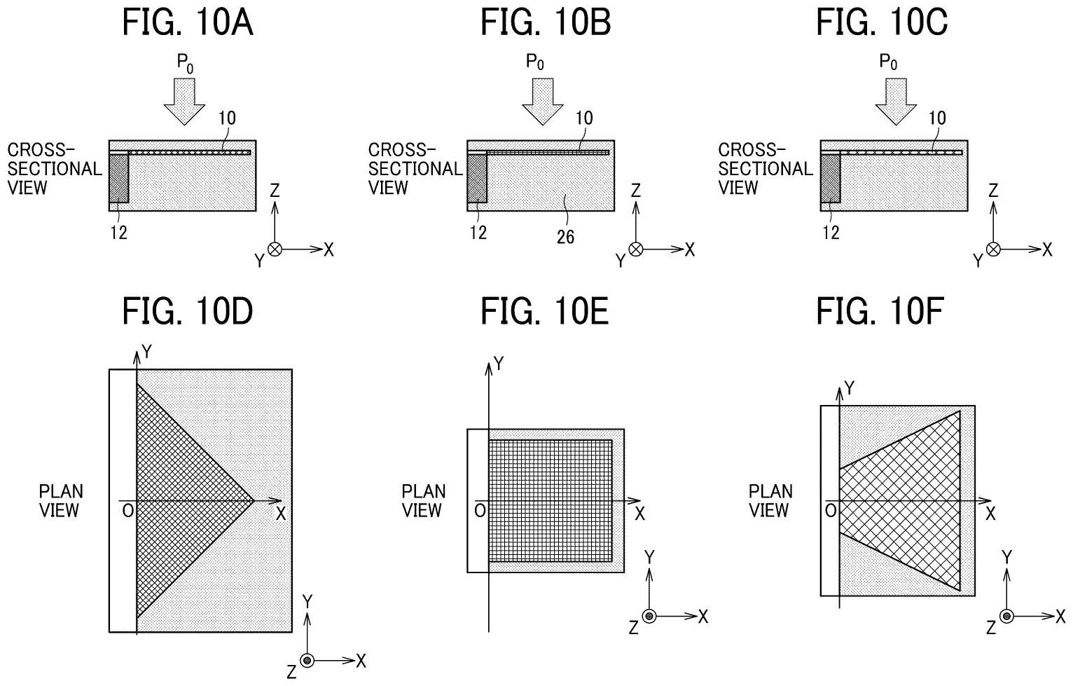

The results of verifying the above effects through simulation are described below. FIGS. 10A, 10B, 10C, 10D, 10E, and 10F are diagrams each illustrating a model used for the simulation according to a second comparative example. In the second comparative example, a diaphragm 10 is triangle.

FIG. b0A is a cross-sectional view of the diaphragm 10 according to the second comparative example. FIG. 10D is a plan view of the diaphragm 10 according to the second comparative example. FIG. 10B is a cross-sectional view of the rectangular diaphragm according to the first comparative example. FIG. 10E is a plan view of the rectangular diaphragm according to the first comparative example. FIG. 10C is a cross-sectional view of the model according to the present embodiment. FIG. 10F is a cross-sectional view of the model according to the present embodiment. The area of the diaphragm is the same in the comparative examples illustrated in FIGS. 10A, 10B, 10D, and 10E and the present embodiment illustrated in FIGS. 10C and 10F.

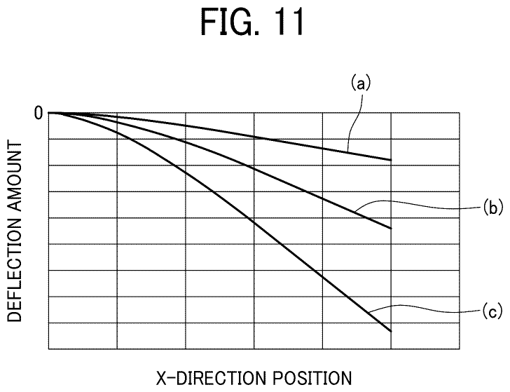

FIG. 11 is a graph of simulation results of the deflection amount for each diaphragm illustrated in FIGS. 10A, 10B, 10C, 10D, 10E, and 10F, under the same acoustic pressure. In FIG. 11, the vertical axis represents the deflection amount, and the horizontal axis represents the position in the X-direction. It is understood that the model of the present embodiment as illustrated in FIGS. 10C and 10F has a larger deflection amount and higher sensitivity than the second comparative example and the first comparative example as illustrated in FIGS. 10A, 10B, 10D, and 10E.

To enhance the sensitivity of the vibration detector 1, the deflection angle at each point of the diaphragm 10 is increased when a uniform pressure is applied to the diaphragm 10. In other words, the area of the diaphragm 10 is increased from a certain point to the tip end to enhance the sensitivity of the vibration detector 1. The diaphragm 10 with a width that continuously increases from the fixed end to the tip end achieves a higher-sensitivity vibration detector 1.

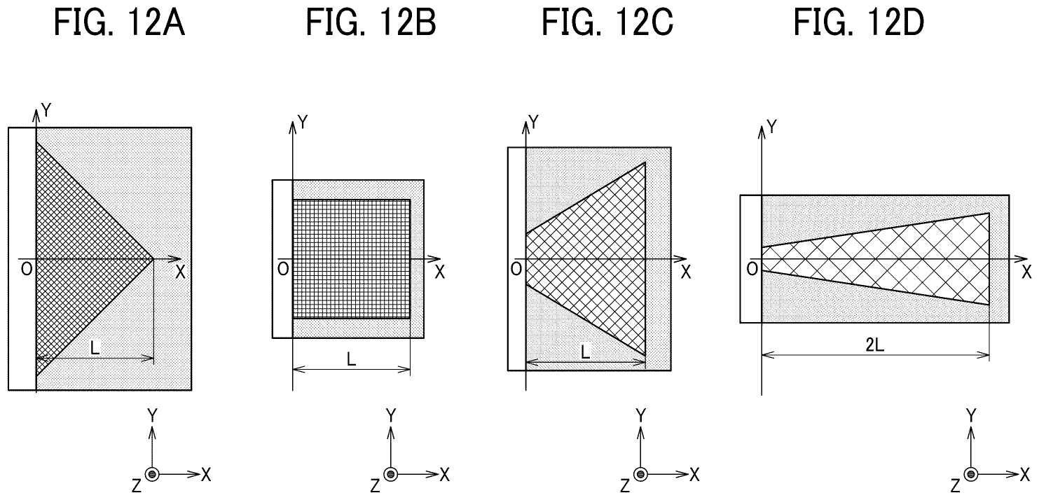

The results of the sensitivity investigation are described below. FIGS. 12A, 12B, and 12C are diagrams each illustrating a shape used for the simulation.

FIG. 12A is a diagram for the second comparative example. FIG. 12B is a diagram for the first comparative example. FIG. 12C is a diagram of the model according to the present embodiment. FIG. 12D is a diagram of a diaphragm with twice the length L from the tip end to the fixed end. The area of the diaphragm is the same in the comparative examples illustrated in FIGS. 12A and 12B and the present embodiment illustrated in FIGS. 12C and 12D.

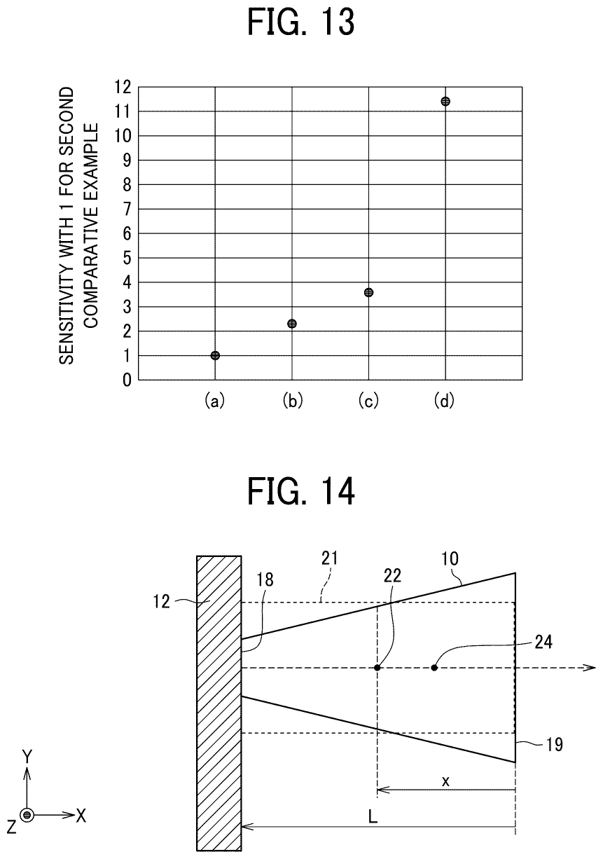

FIG. 13 is a graph of simulation results of the deflection amount for each diaphragm illustrated in FIGS. 12A, 12B, 12C, and 12D under the same acoustic pressure. FIG. 13 presents the sensitivity values, using the sensitivity in FIG. 12A as a reference value of 1. It is understood that the sensitivity of the model of the present embodiment as illustrated in FIG. 12C is increased compared to those of the second comparative example and the first comparative example illustrated in FIGS. 12A and 12B, respectively. Further, it is understood that twice the length from the tip end to the fixed end as illustrated in FIG. 12D exhibits even greater enhancement in sensitivity. The diaphragm 10 with a shape in which the length in the direction orthogonal to the line segment of the fixed end is longer than that along the line segment of the fixed end exhibits even greater enhancement in sensitivity.

The following describes a resonant frequency band of a diaphragm. In the present embodiment, the resonant frequency is in the vicinity of 100 to several kHz. Unlike the common frequency range of several tens of kHz, it is in a lower frequency band. The lower frequency range is suitable for measurements such as hydrophones used for monitoring heartbeats and pipe inspections. Lengthening the diaphragm 10 can lower the frequency, but it also makes the vibration detector 1 larger and reduces the mechanical strength and reliability of the diaphragm 10. Methods to reduce the frequency without lengthening the diaphragm are being explored.

FIG. 14 is a diagram for comparing the center of gravity for the first comparative example with that of the model of the present embodiment. The first comparative example has a rectangular diaphragm 21 as described above. In the case of the first comparative example, the center of gravity is at L/2, which corresponds to point 22 in the center. In contrast, in the model of the present embodiment, the width of the diaphragm closer to the tip end 19 is wider than that of the fixed end 18, causing the center of gravity to be located closer to the tip end 19 than the central portion. The model of the present embodiment has a center of gravity 24. However, the mass per unit volume of the diaphragm 10 and the diaphragm 21 is constant. This can reduce the resonance frequency.

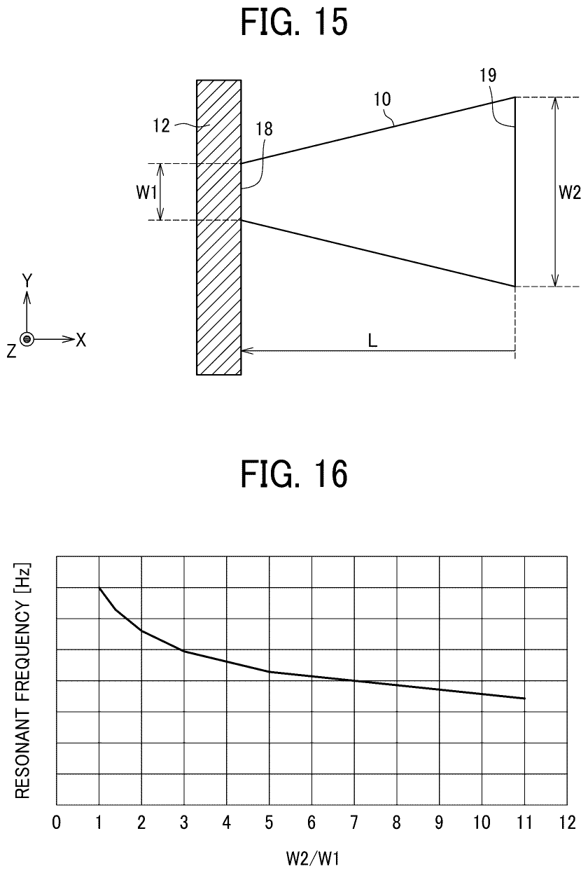

The influence of the shape of the diaphragm on the resonance frequency was investigated through simulation. FIG. 15 is a diagram of a model used for the simulation. In the diaphragm 10, the fixed end 18 has a length W1 along its line segment in the Y-direction, and the tip end 19 has a length W2 along its line segment in the Y-direction. The length W2 of the tip end 19 is measured at the position farthest from the fixed end 18 in the X-direction, which is orthogonal to the line segment of the fixed end 18. When the diaphragm 10 has a quadrangular shape, the side facing the fixed end 18 may have the length W2. The resonant frequency was calculated when the ratio W1/W2 was changed, assuming that the areas (W2+W1)L/2 of the diaphragm 10 and the length L of the cantilever beam are constant. The end shapes other than the fixed end 18 and the tip end 19 are connected in a straight line without any concavities or convexities. The thickness and density of the diaphragm 10 are constant.

FIG. 16 is a graph of the simulation results. The vertical axis represents the resonant frequency. The horizontal axis represents the shape of the diaphragm 10 as W2/W1. It is understood that the resonant frequency decreases as the ratio W2/W1 increases. When W2/W1 is 1 (W2/W1=1), the diaphragm 10 is rectangular, which is the diaphragm 21 of the first comparative example. In other words, compared to the rectangular shape of the first comparative example, designing the tip end with a wider width reduces the resonant frequency. This can be rephrased in terms of the position of the center of gravity described above. Designing the distance between the center of gravity of the diaphragm and the fixed end to be L/2 or greater can reduce the resonant frequency.

The vibration detector 1 according to the present embodiment satisfies a conditional expression below:

$$W 1 / W 2 > 1$$

In the above description, W1 indicates the length of the fixed end 18 of the diaphragm 10 along its line segment in the Y-direction; and W2 indicates the length of the tip end 19 along its line segment in the Y-direction.

In the shape of the diaphragm of the vibration detector 1, the mass increases toward the tip, and thus the resonant frequency decreases, enhancing the sensitivity in the low-frequency band.

### First Modification

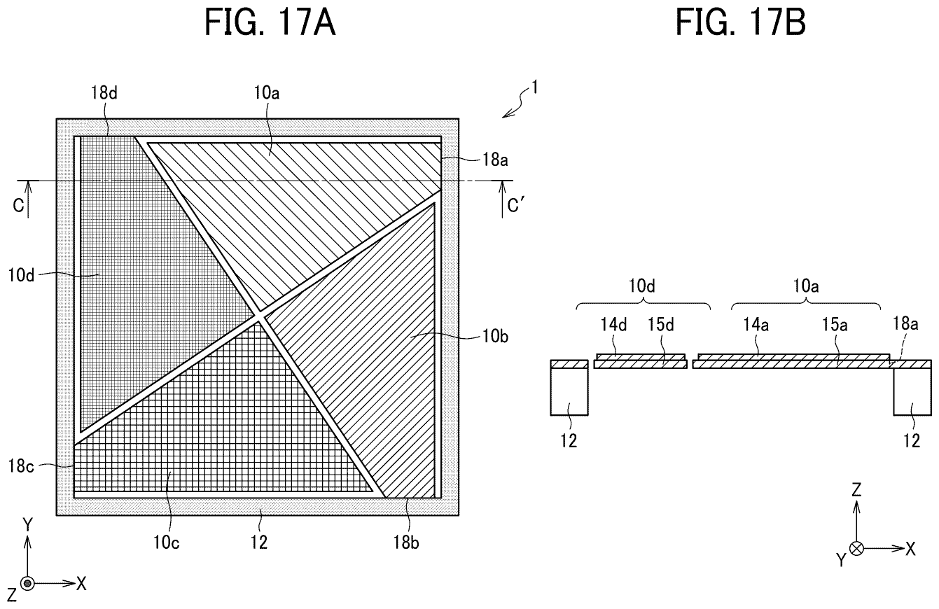

FIG. 17A is a plan view of a vibration detector according to a first modification of the embodiment of the present disclosure. FIG. 17B is a cross-sectional view of the vibration detector of FIG. 17A. In the present modification, the diaphragm 10 includes a first distortion detectors 14 and a second distortion detector 15, which are formed in two layers. Each of the first distortion detectors 14 and the second distortion detector 15 is sandwiched between the lower electrode and the upper electrode. This allows the detection of the degree of distortion of the first distortion detectors 14 and the second distortion detector 15 as a potential generated between the upper electrode and the lower electrode. An insulating layer is formed between the two layers of the first distortion detectors 14 and the second distortion detector 15, electrically separating them. In some examples, the lower electrode of the strain detector 14 and the upper electrode of the distortion detector 15 may be formed as a common electrode without the insulating layer. This allows the potentials of the first distortion detectors 14 and the second distortion detector 15 to be independently detected. The two layers of the first distortion detectors 14 and the second distortion detector 15 overlap in substantially the same area in a plan view. Upon the vibration of the diaphragm caused by external vibrations, the first distortion detectors 14 and the second distortion detector 15 each experience either compressive strain or tensile strain. The first distortion detectors 14 and the second distortion detector 15 generate potentials of opposite signs due to the opposite stresses. By detecting the difference between the two potentials, the signal is doubled. For example, if one is at the potential of 5V and the other is at −5V, the difference between the two potentials is 5V−(−5V)=10V. In other words, it is found that the signal is doubled. In the case of a potential occurring only on one side, the signal is noise. By taking the difference between the signals, the influence of electrical noise can be reduced. The sensitivity can be enhanced by doubling the signal.

The vibration detector 1 according to the present modification has a two-layer structure of the first distortion detectors 14 and the second distortion detector 15. In this configuration, the signal from the second distortion detector 15 is subtracted from the signal from the first distortion detectors 14. This reduces noise and doubles the signal, enhancing the sensitivity further.

### Second Modification

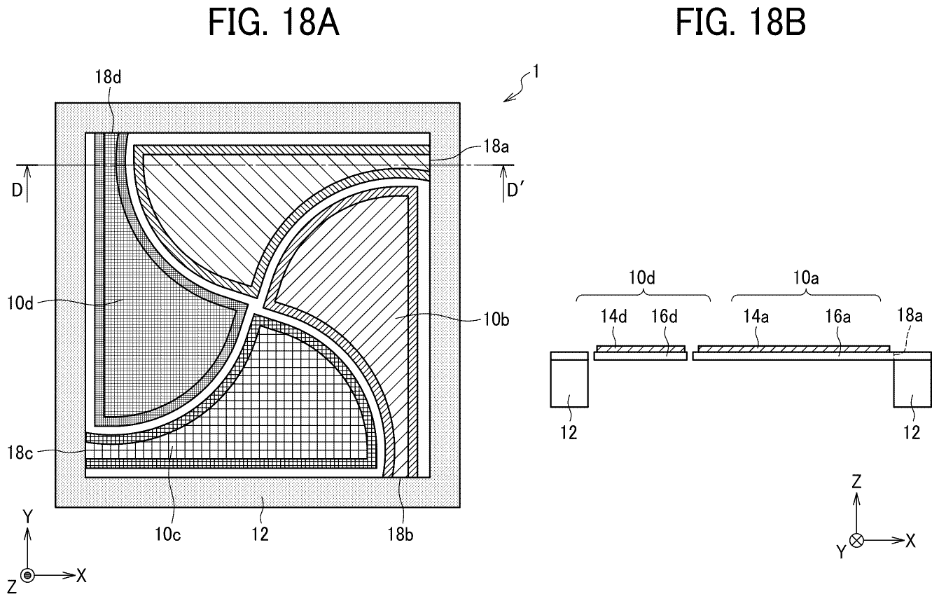

FIG. 18A is a plan view of a vibration detector according to a second modification of the above-described embodiment of the present disclosure. FIG. 18B is a cross-sectional view of the vibration detector of FIG. 18A. The diaphragm 10 has a curved end portion at an end other than the fixed end 18. Designing the diaphragm 10 with a curved shape increases design flexibility. Using this design flexibility, the pressure received at the tip end of the diaphragm 10 can be further increased through design adjustments. Further, the area near the fixed end 18 is narrowed, allowing the the fixed end 18 to be farther from the center of gravity. This enables a greater deflection angle, enhancing the sensitivity of the vibration detector 1.

### Third Modification

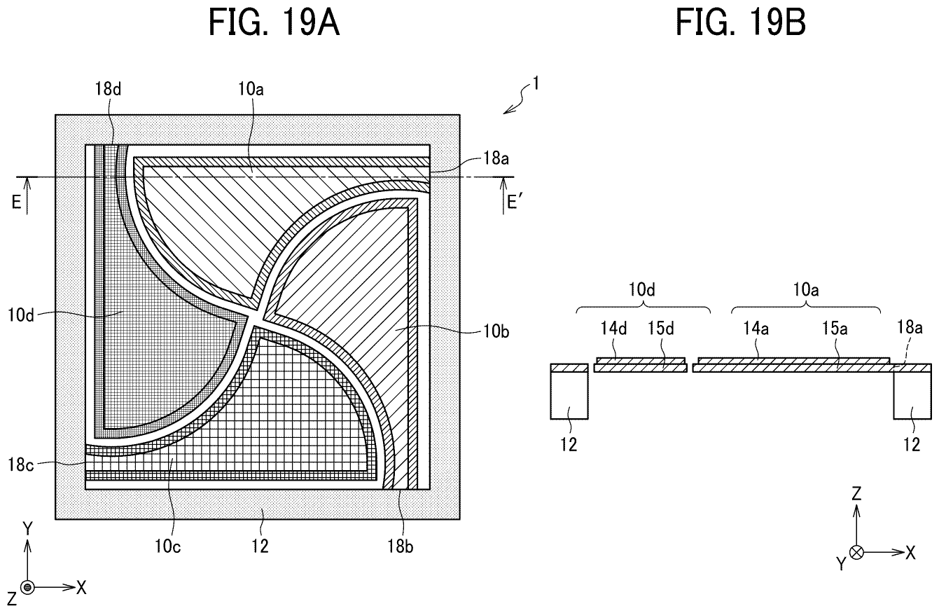

FIG. 19A is a plan view of a vibration detector according to a third modification of the above-described embodiment of the present disclosure. FIG. 19B is a cross-sectional view of the vibration detector of FIG. 19A. The diaphragm 10 has a curved end portion at an end other than the fixed end 18. The first distortion detectors 14 and the second distortion detector 15 are formed in a two-layer structure. Designing the diaphragm 10 with a curved shape increases design flexibility.

Using this design flexibility, the pressure received at the tip end of the diaphragm 10 can be further increased through design adjustments. Using these distortion detectors as the two-layer structure and taking the difference between the signals doubles the signal and reduces noise. This enables a greater deflection angle and optimizes S/N ratio, enhancing the sensitivity of the vibration detector 1.

### Fourth Modification

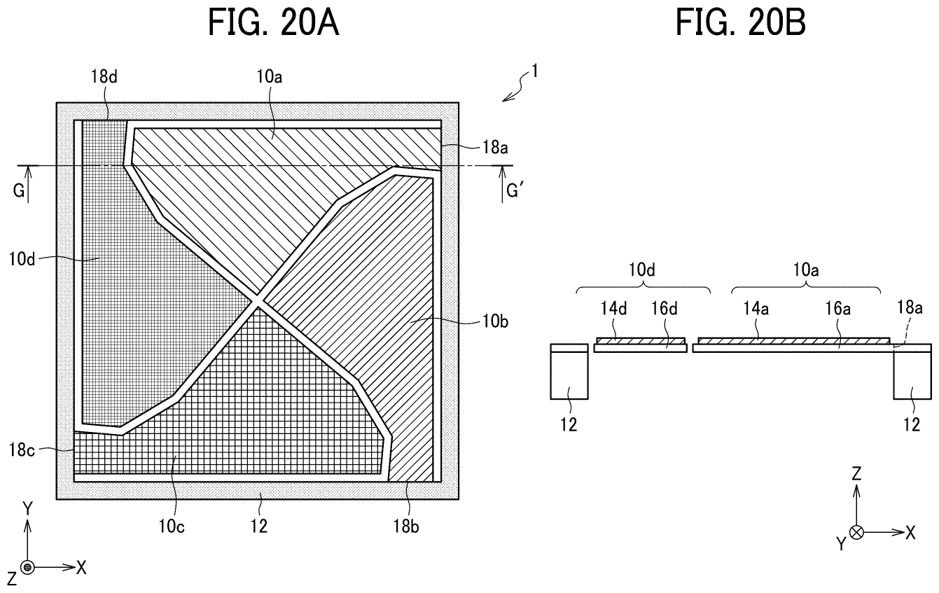

FIG. 20A is a plan view of a vibration detector according to a fourth modification of the above-described embodiment of the present disclosure. FIG. 20B is a cross-sectional view of the vibration detector of FIG. 20A. The diaphragm 10 is polygonal. The polygonal shape includes a wide range of non-quadrangular polygonal shapes, such as polygons with five or more vertices in the diaphragm. Compared to curved shapes, the polygonal shape is more resistant to manufacturing errors in the semiconductor process due to the anisotropy of the silicon crystal. Further, the design flexibility increases for the polygonal shape compared to the case of the quadrangular diaphragm as illustrated in FIG. 1. Using this design flexibility, the pressure received at the tip end of the diaphragm 10 can be further increased through design adjustments. This enables a greater deflection angle, enhancing the sensitivity of the vibration detector 1.

### Fifth Modification

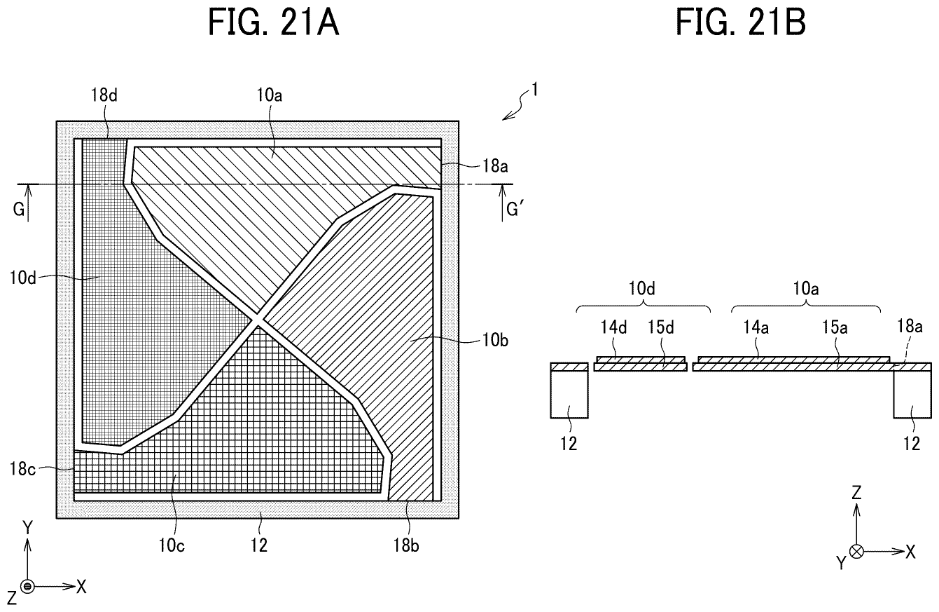

FIG. 21A is a plan view of a vibration detector according to a fifth modification of the above-described embodiment of the present disclosure. FIG. 21B is a cross-sectional view of the vibration detector of FIG. 21A. The diaphragm 10 has a polygonal shape. The first distortion detectors 14 and the second distortion detector 15 are formed in a two-layer structure. The polygonal shape includes a wide range of non-quadrangular polygonal shapes, such as polygons with five or more vertices in the diaphragm. Compared to curved shapes, the polygonal shape is more resistant to manufacturing errors in the semiconductor process due to the anisotropy of the silicon crystal.

Further, the design flexibility increases for the polygonal shape compared to the case of the quadrangular diaphragm as illustrated in FIG. 1. Using this design flexibility, the pressure received at the tip end of the diaphragm 10 can be further increased through design adjustments. Using these distortion detectors as the two-layer structure and taking the difference between the signals doubles the signal and reduces noise. This enables a greater deflection angle and optimizes S/N ratio, enhancing the sensitivity of the vibration detector 1.

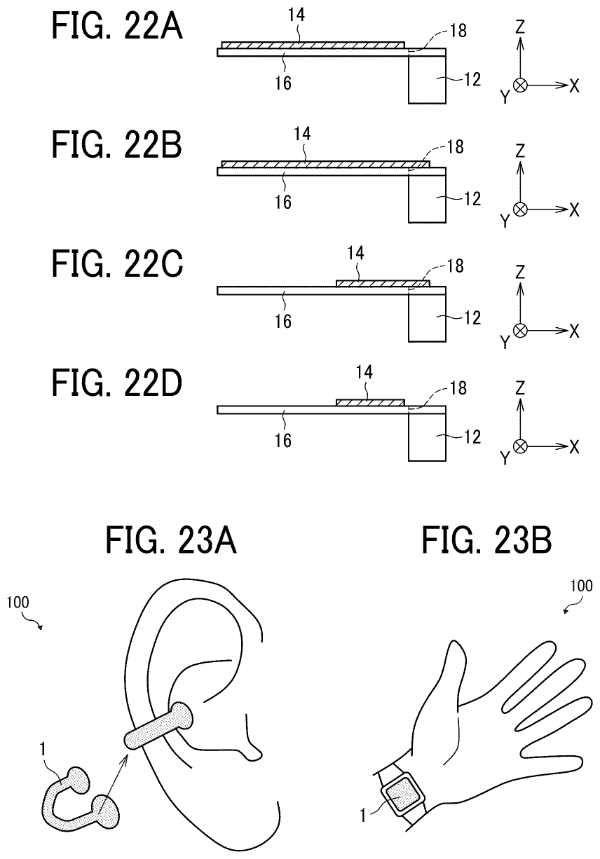

FIGS. 22A, 22B, 22C, and 22D are diagrams each illustrating a different relative position between the distortion detector 14 and the support portion 12 according to a modification of the above-described embodiment. If the distortion detector 14 is placed closer to the fixed end 18 on the diaphragm 10, it can be positioned in various locations, including on the support portion 12. For example, as illustrated in FIG. 22A, the distortion detector 14 may be placed to cover the entire diaphragm 10. As illustrated in FIG. 22B, the distortion detector 14 may be placed extending over the support portion 12. As illustrated in FIG. 22C, the distortion detector 14 may be placed on a part of the diaphragm 10 adjacent to the fixed end 18, instead of covering the entirety of the diaphragm 10. As illustrated in FIG. 22D, the distortion detector 14 may be placed only in the vicinity of the fixed end 18. The amount of distortion detected by the distortion detector 14 upon receiving vibration at the vibration detector 1 increases as it gets closer to the fixed end 18 on the diaphragm 10. As such, the distortion detector 14 is placed closer to the fixed end 18 on the diaphragm 10, enhancing the sensitivity of the vibration detector 1.

### Second Embodiment

In the present embodiment, the vibration detector 1, which has enhanced the sensitivity in the low-frequency range, is incorporated into a wearable sensor to accurately detect human heartbeats.

The present embodiment relates to a vibration detector 1 that detects pulse waves of the heartbeat with minimal noise. The wearable device incorporating the vibration detector 1 serve to convert information related to various data such as the heartbeat, the heart rate (pulse rate), the blood pressure, the breathing sound, and the breathing rate detected by the vibration detector 1 into vital data. The vibration detector 1 is mounted on an ear as illustrated in FIG. 23A or a wrist as illustrated in FIG. 23B and used as a wearable sensor 100 (or a wearable device). The sound waves generated when the peripheral blood vessels expand due to the heartbeat in a low-frequency band of about 100 Hz. The vibration detector 1 of the present embodiment has high sensitivity to frequencies equal to or lower than 100 Hz due to the broad shape of the tip of the diaphragm 10.

In the present embodiment, the occurrence of noise can be greatly reduced by detecting the heartbeat through sound. In the detection of the heartbeat by light, it is difficult to measure an accurate waveform due to noise from ambient light and changes in the wearing state caused by body motion. Thus, this method is limited to specific uses such as measuring pulse rate. Compared to typical pulse wave sensors using light, utilizing sound can reduce noise, allowing for more accurate analysis of the frequency components from the detected pulse waves.

In the present embodiment, analyzing the frequency components of pulse waves allows for a more accurate understanding of the psychological state. By applying machine learning to the analysis of frequency components, information related to the heartbeat can be interpreted with high accuracy, allowing for a multifaceted estimation of the psychological state.

The wearable device according to the present embodiment may be equipped with a system to detect the psychological state of office workers. By wearing the wearable sensor of the present embodiment during tasks such as meetings, programming, email writing, and one-on-one sessions with a supervisor, heart rate can be monitored, and psychological states (such as stress and concentration levels) can be detected.

The system of the present embodiment features a user interface (UI) for visualizing changes in psychological states, such as concentration and stress levels. Specifically, the UI can display graphs and tables that show how stress and concentration levels change during various tasks, allowing users to intuitively understand these changes.

Further, the system utilizes machine learning to analyze factors that affect concentration, such as time of day, meeting partners, and work environment. This analysis proposes optimal task environments for users and supports effective scheduling. Additionally, when the user feels stress due to a decrease in concentration, the system can issue an alarm to prompt the user to relax.

### Third Embodiment

The present embodiment relates to a vibration detector for detecting the location of water leaks. Conventional sensors are based on piezoelectric ceramics, which have high acoustic impedance and limited sensitivity. However, the present embodiment utilizes the MEMS technology, achieving higher sensitivity, miniaturization, and lower costs compared to piezoelectric ceramic sensors.

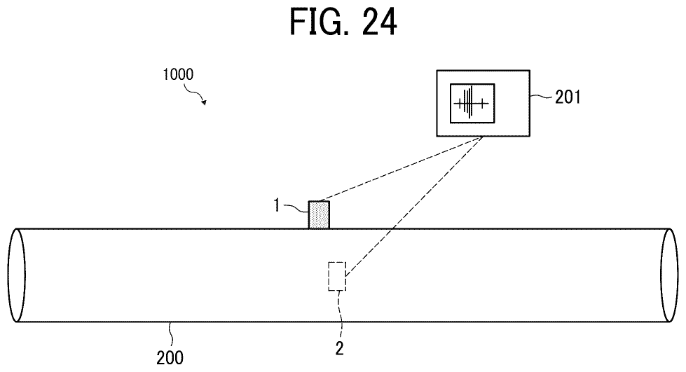

In the present embodiment, the vibration detector 1 is installed in a water pipe 200 as illustrated in FIG. 24, serving as a piping inspection apparatus 1000 to detect the location of water leaks. As illustrated in FIG. 24, the vibration detector 1 is used as a microphone. Vibration transmitted to the surface of the water pipe 200 is detected as sound. Further, a vibration detector 2 is installed inside the water pipe 200 as a hydrophone to perform simultaneous detection. The hydrophone detects sounds transmitted to the water pipe 200 from vibration transmitted through water. Detecting vibrations through the medium of water reduces their attenuation, allowing for the detection of vibration sources at farther distances than through the medium of air. Further, by using the microphone and the hydrophone at the same time, it is possible to enhance detection accuracy. Hydrophones are enhanced by detecting low frequencies of a few hundred Hz. This method can inspect distances of up to 1 km, making it excellent for large-scale pipeline inspections. The vibration detector 1 (e.g., a microphone) and the vibration detector 2 (e.g., a hydrophone) transmit detection signals wirelessly to an arithmetic device 201. The signals are synchronized in a time series to analyze the location of water leaks.

Aspects of the present disclosure are as follows.

### Aspect 1

A vibration detector 1 of the present embodiment includes: a diaphragm 10 including: a fixed end 18 forming a line segment extending in a first direction; and a reference point (e.g., 19) farthest from the fixed end on an outer periphery of the diaphragm 10 in a second direction orthogonal to the first direction; and a support portion 12 supporting the diaphragm 10 at the fixed end 18 to allow the diaphragm 10 to vibrate. The vibration detector 1 satisfies a formula below:

$$\frac{{L}^{3}}{8 {W}_{0}} < {\int }_{0}^{L} \int \frac{1}{W ( x )} {\int }_{0}^{x} W ( ξ ) ξ d ξ {dx}^{2}$$

where x denotes a distance in the second direction between the reference point (e.g., 19) and a point on the diaphragm 10, denotes a point within a distance of x from the reference point (e.g., 19) in the second direction, W(x) denotes a width of the diaphragm 10 at the distance of x in the first direction, L denotes a length of the diaphragm 10 between the fixed end and the reference point (e.g., 19) in the second direction, and W0 denotes a width of the diaphragm 10 in the first direction when the diaphragm 10 has a rectangular shape with the length L and a constant area.

This provides a vibration detector 1 with higher sensitivity in the low-frequency range.

### Aspect 2

In the vibration detector 1 according to Aspect 1, the diaphragm 10 has at least two areas divided by a straight line 58 in the first direction, passing through a midpoint 54 of a line segment shortest among line segments between the fixed end 18 and the outer periphery of the diaphragm 10 in the second direction, the two areas including: a first area 62 adjacent to the fixed end 18 relative to the straight line 58; and a second area 64 opposite to the first area 62 relative to the straight line 58 and greater than the first area 62.

This provides a vibration detector 1 with higher sensitivity in the low-frequency range.

### Aspect 3

A vibration detector 1 of the present embodiment includes: a diaphragm 10 including a fixed end 18 forming a line segment extending in a first direction; and a support portion 12 supporting the diaphragm 10 at the fixed end 18 to allow the diaphragm 10 to vibrate. A width of the diaphragm in the first direction is maximum at a position farther from the fixed end 18 than a midpoint 54 of a line segment shortest among line segments between the fixed end 18 and an outer periphery of the diaphragm 10 in the second direction.

### Aspect 4

The vibration detector 1 according to any one of Aspect 1 to Aspect 3, further includes a distortion detector 14 to detect distortion of the diaphragm 10.

This further enhances the sensitivity of the vibration detector.

### Aspect 5

In the vibration detector 1 according to any one of Aspect 4, the distortion detector 14 includes at least two layers of a first distortion detector and a second distortion detector. This reduces noise and doubles the signal, enhancing the sensitivity further.

### Aspect 6

In the vibration detector 1 according to any one of Aspect 1 to Aspect 5, the vibration detector 1 satisfies a conditional expression below:

W2/W1>1
where
W1 denotes a length of the fixed end 18 in the first direction, and
W2 denotes a width of the diaphragm 10 in the first direction at a point farthest from the fixed end 18 in the second direction.

This reduces resonant frequency and enhances the sensitivity in the low-frequency range.

### Aspect 7

In the vibration detector 1 according to any one of Aspect 1 to Aspect 6, the diaphragm 10 has a substantially quadrilateral, and the vibration detector 1 satisfies a conditional expression below:

W2/W1>1
where
W1 denotes a length of the fixed end 18 in the first direction, and
W2 denotes a length of a side of the diaphragm 10 opposed to the fixed end 18 in the second direction.

This increases the design flexibility of the shape of the diaphragm 10, enhancing the sensitivity further.

### Aspect 8

In the vibration detector 1 according to any one of Aspect 1 to Aspect 6, the diaphragm 10 is polygonal with five or more sides. This increases the design flexibility of the shape of the diaphragm 10, enhancing the sensitivity further.

### Aspect 9

In the vibration detector 1 according to any one of Aspect 1 to Aspect 8, the diaphragm 10 includes a curved shape. This increases the design flexibility of the shape of the diaphragm 10, enhancing the sensitivity further.

### Aspect 10

A wearable device 100 includes the vibration detector 1 according to any one of Aspect 1 to Aspect 9. This enables the acquisition of accurate vital data.

### Aspect 11

In the vibration detector according to Aspect 1, the diaphragm has the width continuously increasing from the fixed end to the tip end in the second direction.

### Aspect 12

A piping inspection apparatus 1000 includes the vibration detector 1 according to any one of Aspect 1 to Aspect 9 to detect vibration of a water pipe; and an arithmetic device 201 configured to analyze a location of a water leak based on a signal corresponding to the vibration detected by the vibration detector 1.

This allows for the estimation of the precise location of defects in the piping.

### Aspect 13

A vibration detector includes a cantilever beam including: a support portion 12; and a diaphragm 10 including a fixed end 18 fixed to the support portion 12; and a tip end 19 farther from the fixed end in a first direction (e.g., the X-direction), the tip end 19 vibratile in a second direction (e.g., the Z-direction) intersecting the first direction (e.g., the X-direction). The diaphragm 10 has a part having a width in a third direction (e.g., the Y-direction) intersecting the first direction (e.g., the X-direction) and the second direction (e.g., the Z-direction). The width of the part continuously increases from the fixed end 18 toward the tip end 19 in the first direction (e.g., the X-direction).

The above-described embodiments are illustrative and do not limit the present invention. Thus, numerous additional modifications and variations are possible in light of the above teachings. For example, elements and/or features of different illustrative embodiments may be combined with each other and/or substituted for each other within the scope of the present invention.

The functionality of the elements disclosed herein may be implemented using circuitry or processing circuitry which includes general purpose processors, special purpose processors, integrated circuits, application-specific integrated circuits (ASICs), field-programmable gate arrays (FPGAs), and/or combinations thereof which are configured or programmed, using one or more programs stored in one or more memories, to perform the disclosed functionality. Processors are considered processing circuitry or circuitry as they include transistors and other circuitry therein. In the disclosure, the circuitry, units, or means are hardware that carry out or are programmed to perform the recited functionality. The hardware may be any hardware disclosed herein which is programmed or configured to carry out the recited functionality.

There is a memory that stores a computer program which includes computer instructions. These computer instructions provide the logic and routines that enable the hardware (e.g., processing circuitry or circuitry) to perform the method disclosed herein. This computer program can be implemented in known formats as a computer-readable storage medium, a computer program product, a memory device, a record medium such as a CD-ROM or DVD, and/or the memory of an FPGA or ASIC.

1. A vibration detector comprising:
a diaphragm including:
a fixed end forming a line segment extending in a first direction; and
a reference point farthest from the fixed end on an outer periphery of the diaphragm in a second direction orthogonal to the first direction; and
a support portion supporting the diaphragm at the fixed end to allow the diaphragm to vibrate,
wherein the vibration detector satisfies a formula below:
$$\frac{{L}^{3}}{8 {W}_{0}} < {\int }_{0}^{L} \int \frac{1}{W ( x )} {\int }_{0}^{x} W ( ξ ) ξ d ξ {dx}^{2}$$
where
x denotes a distance in the second direction between the reference point and a point on the diaphragm,
ξ denotes a point within a distance of x from the reference point in the second direction,
W(x) denotes a width of the diaphragm at the distance of x in the first direction,
L denotes a length of the diaphragm between the fixed end and the reference point in the second direction, and
W0 denotes a width of the diaphragm in the first direction when the diaphragm has a rectangular shape with a length of L and a constant area.

2. The vibration detector according to claim 1,
wherein the diaphragm has at least two areas divided by a straight line in the first direction, passing through a midpoint of a line segment shortest among line segments between the fixed end and the outer periphery of the diaphragm in the second direction, the two areas including:
a first area adjacent to the fixed end relative to the straight line; and
a second area opposite to the first area relative to the straight line and greater than the first area.

3. The vibration detector according to claim 1, further comprising a distortion detector to detect distortion of the diaphragm.

4. The vibration detector according to claim 3,
wherein the distortion detector includes at least two layers of a first distortion detector and a second distortion detector.

5. The vibration detector according to claim 1,
wherein the vibration detector satisfies a conditional expression below:
$$W 2 / W 1 > 1$$
where
W1 denotes a length of the fixed end in the first direction, and
W2 denotes a width of the diaphragm in the first direction at a point farthest from the fixed end in the second direction.

6. The vibration detector according to claim 1,
wherein the diaphragm has a substantially quadrilateral, and
the vibration detector satisfies a conditional expression below:
W2/W1>1
where
W1 denotes a length of the fixed end in the first direction, and
W2 denotes a length of a side of the diaphragm opposed to the fixed end in the second direction.

7. The vibration detector according to claim 1,
wherein the diaphragm is polygonal with five or more sides.

8. The vibration detector according to claim 1,
wherein the diaphragm includes a curved shape.

9. A wearable device comprising the vibration detector according to claim 1.

10. A piping inspection apparatus comprising:
the vibration detector according to claim 1 to detect vibration of a water pipe; and
circuitry configured to analyze a location of a water leak based on a signal corresponding to the vibration detected by the vibration detector.

11. The vibration detector according to claim 1,
wherein the diaphragm has the width continuously increasing from the fixed end to the tip end in the second direction.

12. A vibration detector comprising:
a diaphragm including a fixed end forming a line segment extending in a first direction; and
a support portion supporting the diaphragm at the fixed end to allow the diaphragm to vibrate,
wherein a width of the diaphragm in the first direction is maximum at a position farther from the fixed end than a midpoint of a line segment shortest among line segments between the fixed end and an outer periphery of the diaphragm in a second direction orthogonal to the first direction.

13. A vibration detector comprising:
a cantilever beam including:
a support portion; and
a diaphragm including:
a fixed end fixed to the support portion; and
a tip end farther from the fixed end in a first direction, the tip end vibratile in a second direction intersecting the first direction,
the diaphragm having a part having a width in a third direction intersecting the first direction and the second direction, and
the width of the part continuously increasing from the fixed end toward the tip end in the first direction.
